(19) United States
(12) Patent Application Publication
(10) Pub. No.: US 2007/0085709 A1
(43) Pub. Date: Apr. 19, 2007

(54) Symbol detection apparatus and method for two-dimensional channel data stream with cross-talk cancellation

(75) Inventors: Willem Marie Julia Marcel Coene, Eindhoven (NL); Albert Hendrik Jan Immink, Eindhoven (NL); Thomas Conway, Birr (IE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC, N.V., EINDHOVEN (NL)

(21) Appl. No.: 10/596,080

(22) PCT Filed: Nov. 18, 2004
(86) PCT No.: PCT/IB04/52472

§ 371 Date: May 30, 2006

(30) Foreign Application Priority Data
Dec. 3, 2003 (EP) 03104526.3

(51) Int. Cl. H03M 7/00

(52) U.S. Cl. 341/50

(57) ABSTRACT

The present invention relates to a symbol detection apparatus for detecting the symbol values of a two-dimensional channel data stream recorded on a record carrier, said channel data stream comprising a set of contiguous symbol strips (B) of symbol rows (r) onedimensionally evolving along a first direction and being aligned with each other along a second direction, said two directions constituting a two-dimensional lattice of symbol positions. In order to avoid a substantial loss in detection performance at the edges of a 2D symbol strip in a 2D format, a symbol detector apparatus is proposed comprising: a cross-talk cancellation unit (XTC) for cancellation of radial inter-symbol interference, also known as cross-talk or inter-track interference, present in the first adjacent symbol rows (g₀₁, g₀₂; rᵣ₁′r_{N+2})of a symbol strip (B1) from the next but one adjacent symbol row (rb₀₁, rb₀₂; r0, r_{N+3}) of said symbol strip (B1) by applying for each first adjacent symbol row (g₀₁, g₀₂; r₁, r_{N+2}) a cross-talk cancellation between a first adjacent symbol row (g₀₁, g₀₂; r₁, r_{N+2}) and its neighboring symbol row (rb₀₁, rb₀₂; r₀, r_{N+3}) not belonging to said symbol strip (B1), and a 2D symbol detector (V) for symbol detection of the symbols of said symbol strip (B1) together with said first adjacent symbol rows (g₀₁, g₀₂; r₁, r_{N+2})

The present invention relates to a symbol detection apparatus for detecting the symbol values of a two-dimensional channel data stream recorded on a record carrier, said channel data stream comprising a set of contiguous symbol strips of symbol rows one-dimensionally evolving along a first direction and being aligned with each other along a second direction, said two directions constituting a two-dimensional lattice of symbol positions. Further, the present invention relates to a corresponding symbol detection method, a reproduction apparatus and method and to a computer program for implementing said methods.

A potential new route for the next generation of optical recording technology that will succeed Blu-ray Disc (BD) already succeeding DVD (Digital Video Disc) technology is based on two-dimensional (2D) binary optical recording. 2D recording means that e.g. 10 tracks are recorded in parallel on the disc without guard space (or guard band) in between. Then, the 10 tracks together form one big spiral. The format of a disc for 2D optical recording (called in short a “2D disc”) is based on that broad spiral, in which the information is recorded in the form of 2D features. The information is preferably written on a 2D quasi close-packed bit-lattice, for instance as a honeycomb-like structure using a (possibly distorted) hexagonal lattice and is encoded with a 2D channel code, which facilitates bit-detection.

The 2D disc shall be read out with an array of e.g. 10 (or more) optical spots, which are sampled in time, in order to obtain a two dimensional array of samples of the signal waveform in the player. Parallel read out is realized using a single laser beam, which passes through a grating, which produces the array of laser spots. The array of spots scans the full width of the broad spiral. The light from each laser spot is reflected by the 2D pattern on the disc, and is detected on a photo-detector IC, which generates a number of high-frequency signal waveforms. The set of signal waveforms is used as the input of the 2D signal processing. The motivation behind 2D recording is that much less disc space is wasted as guard space, so that the recording capacity of the disc can be increased. Although 2D recording is first studied for optical recording, similarly, magnetic recording can also be made two-dimensional.

For high-density 2D optical storage (preferably having a factor of 2× capacity of BD), the 2D impulse response of the linearized channel can be approximated to a reasonable level of accuracy by a central tap with tap-value c₀ equal to 2, and with 6 nearest-neighbour taps with tap-value c₁ equal to 1. The total energy of this 7-tap response equals 10, with an energy of 6 along the tangential direction (central tap and two neighbour taps), and an energy of 2 along each of the neighbouring symbol rows (each with two neighbour taps).

From these energy considerations, one of the main advantages of 2D modulation can be argued to be the aspect of “joint 2D symbol detection”, where all the energy associated with each single symbol is used for symbol detection. This is in contrast to 1D detection with standard cross-talk cancellation, where only the energy “along-track” is being used, thus yielding a 40% loss of energy per symbol.

A similar argumentation holds when symbol detection at the edges of a 2D symbol strip is considered, a symbol strip consisting of a limited number of symbol rows (in the radial direction). In case the spot-array would only sample the symbol rows of the 2D symbol strip, then at the boundary rows the leaked-away information into the neighboring symbol rows (which could be the symbol row of a guard band, when the 2D symbol strip equals the 2D broad spiral as used in the known 2D format) would not be used. This results. in a loss of 20% per symbol in the top and bottom symbol rows of the 2D symbol strip. Consequently, this would lead to a loss in symbol detection performance at the outer rows of the 2D symbol strip. Moreover, a similar argumentations hold when a 2D symbol strip represents a number of consecutive symbol rows that are part of a substantially larger 2D storage area on a disc or card, wherein the larger storage area makes use of the same 2D bit lattice, possibly including local lattice deformations and lattice defects.

It is an object of the present invention to provide a symbol detection apparatus and method by which a substantial loss in detection performance at the edges of a 2D symbol strip in a 2D format can be avoided.

This object is achieved according to the present invention by a symbol detection apparatus as claimed in claim 1, comprising:

a cross-talk cancellation unit for cancellation of radial inter-symbol interference present in the first adjacent symbol rows of a symbol strip from the next but one adjacent symbol row of said symbol strip by applying for each first adjacent symbol row a cross-talk cancellation between a first adjacent symbol row and its neighboring symbol row not belonging to said symbol strip, and

a 2D symbol detector for symbol detection of the symbols of said symbol strip together with said first adjacent symbol rows.

The present invention relates also to a reproduction apparatus for reproduction of a user data stream from a two-dimensional channel data stream recorded on a record carrier, comprising such a symbol detection apparatus for detecting the symbol values of said two-dimensional channel data stream.

A corresponding symbol detection method and a corresponding reproduction method are defined in claims 6 and 8. A computer program for implementing said methods is defined in claim 9. Preferred embodiments of the invention are defined in the dependent claims.

The invention is based on the idea to use the “leaked-away” information outside the area of the 2D symbol strip. Therefore, the samples of the HF waveform in the symbol rows just outside of the 2D symbol strip, i.e. the first and second (next but one) adjacent symbol rows on both sides of the 2D symbol strip, are used. However, due to 2D inter-symbol interference (ISI), this cannot be done as simply as it appears.

According to the invention it is proposed to measure also the HF signal at the first and second symbol rows of the 2D symbol strip that is adjacent to the current 2D symbol strip and to perform cross-talk cancellation (XTC) at the first adjacent symbol row using the first and second adjacent symbol rows as input. In that case the influence or inter-symbol interference, also known as cross-talk or inter-track interference, of the second adjacent symbol row on the first adjacent symbol row has not to be accounted for in the reference level to be used in the branch metrics of the Viterbi algorithm, but the HF signal is directly compensated, prior to symbol detection. The first adjacent symbol row will thus be (almost) free of inter-symbol interference from the second adjacent symbol rows. Subsequently, all symbol rows of the current 2D symbol strip and the first adjacent symbol rows (at each side of the strip) will be inputted into a 2D symbol detector to detect the symbol values of the symbols in the symbol rows of the current 2D symbol strip.

According to preferred embodiments the first adjacent symbol rows of the current 2D symbol strip are either are guard-band symbol rows separating two contiguous symbol strips, for instance in case of storage of the channel data stream along a broad spiral on a circular disc, or the outer symbol rows of the two neighboring symbol strips, for instance in case of storage of the channel data stream as a large-area continuous 2D format on a card memory device.

Generally, different kinds of 2D symbol detectors can be used for symbol detection after cross-talk cancellation at the first adjacent symbol rows as described above. However, preferred is the use of a 2D PRML symbol detector, in particular a Viterbi detector, for iterative stripe-wise symbol detection of the symbols of a stripe, a stripe comprising at least two neighboring symbol rows. Such stripe-wise symbol detectors are described in European patent application 02292937.6, which can be applied in the symbol detectors of the present invention. To avoid repetitions reference is herewith made to this document.

Further, different embodiments of a cross-talk cancellation unit can be employed according to the invention. A preferred embodiment uses an FIR (FIR=finite impulse response) filter to be applied on the HF samples of the signal waveform of the symbol row to be cancelled; adaptation of the tap-coefficients of the FIR filter can, for instance, be obtained through a least-mean-squares (LMS) method performed by an updating unit as is well known. Also a minimization procedure using the error-signal generated in the Viterbi detector is a possible route.

The invention will now be explained in more detail with reference to the drawings in which:

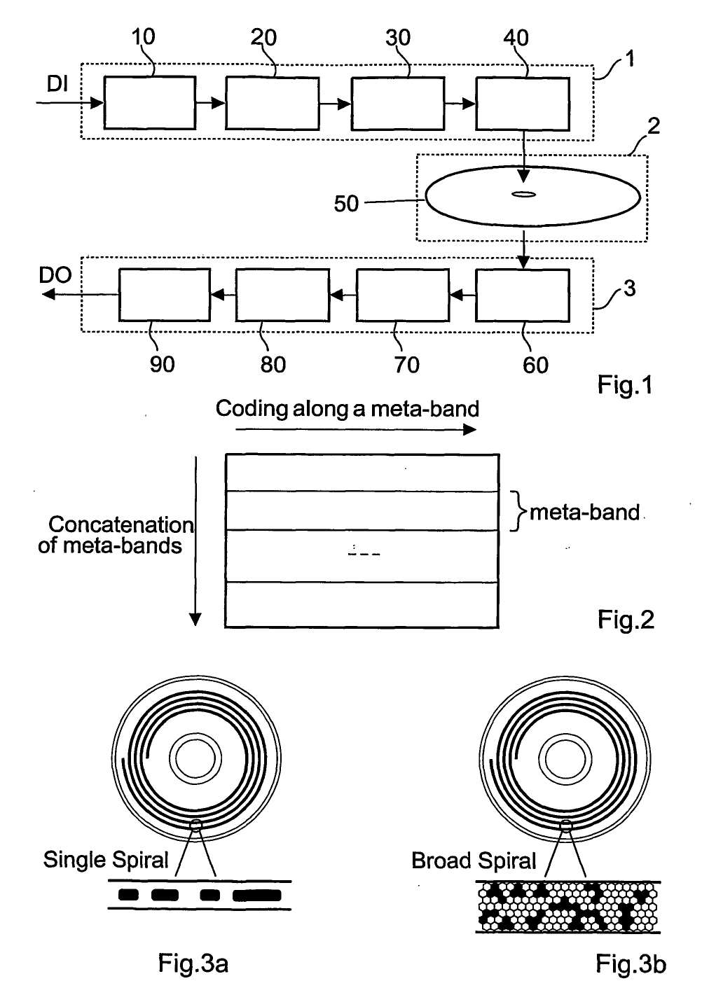

FIG. 1 shows a block diagram illustrating a recording and reproduction system,

FIG. 2 shows a schematical diagram illustrating the principle of strip-based 2D coding,

FIG. 3 shows diagrammatic top-views of 1D and 2D spirals for illustrating 1D and 2D coding concepts,

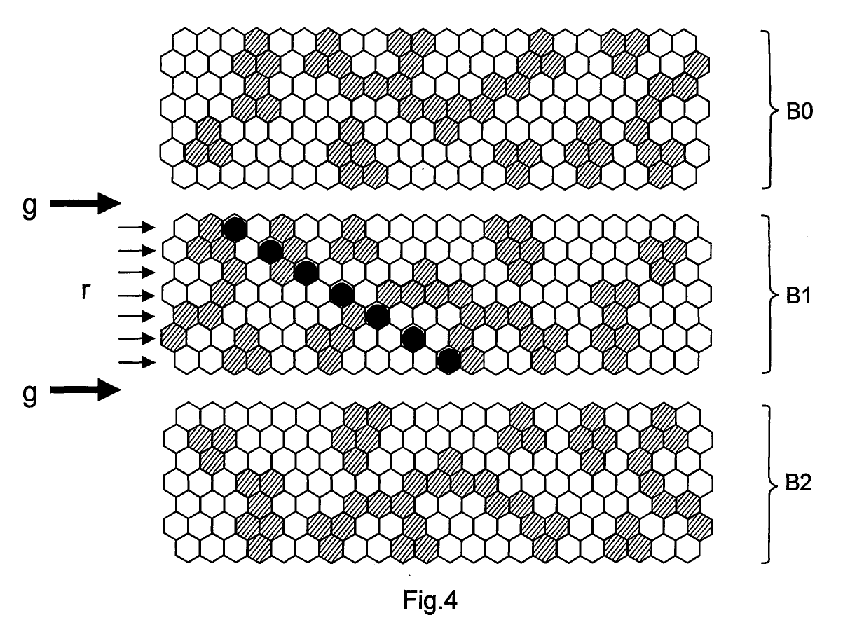

FIG. 4 shows a schematic diagram of a 2D channel data stream as stored on a disc, with guard bands in between consecutive broad spirals,

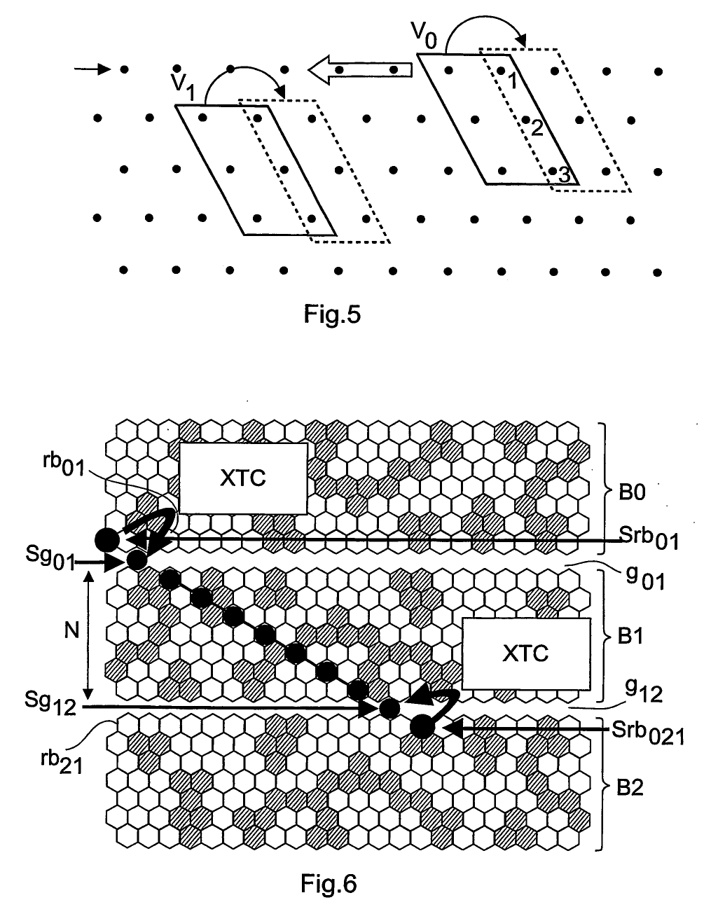

FIG. 5 shows a schematic diagram illustrating the principle of a stripe-wise Viterbi symbol detector,

FIG. 6 illustrates the problem of cross-talk in a 2D channel data stream as stored on a disc,

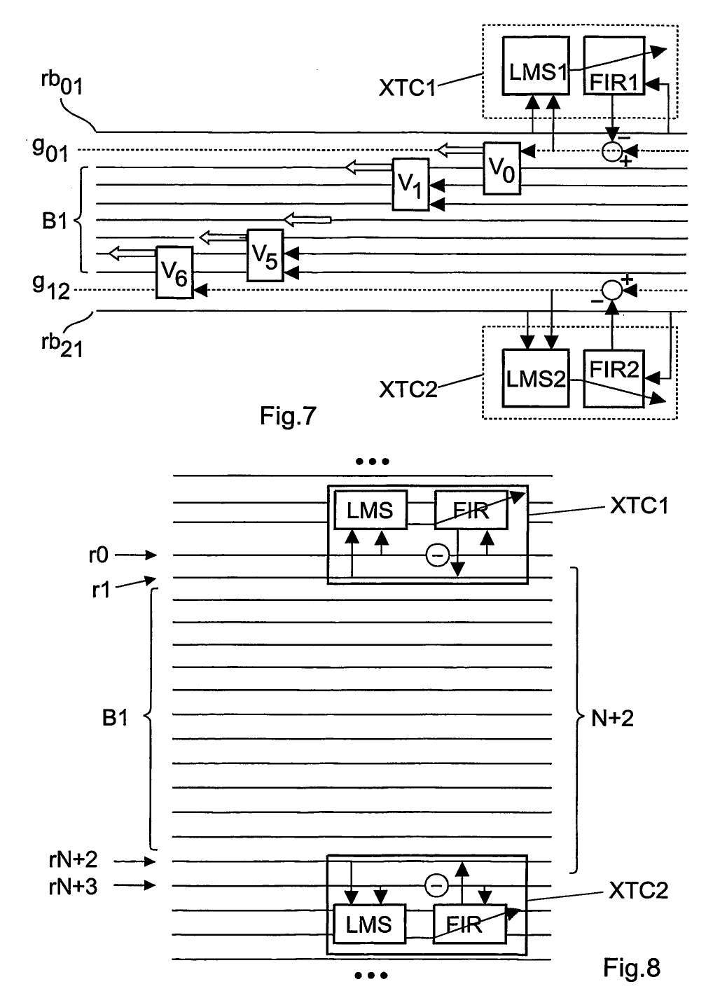

FIG. 7 schematically shows a first embodiment of a symbol detector according to the invention,

FIG. 8 schematically shows a second embodiment of a symbol detector according to the invention,

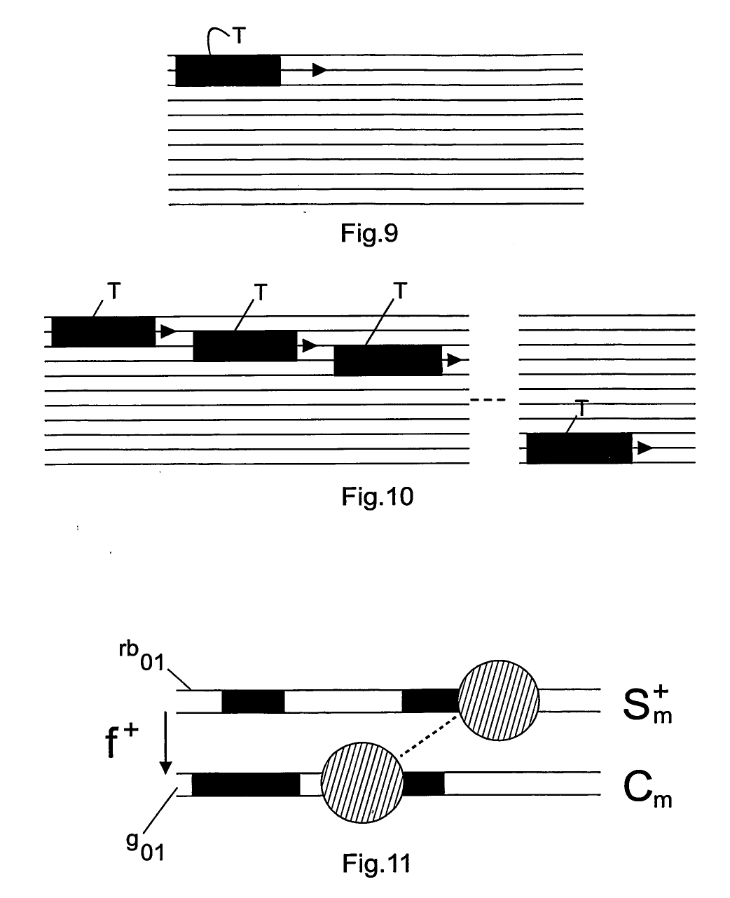

FIG. 9 shows a schematic diagram illustrating an example of stripe-wise symbol detection in a first embodiment,

FIG. 10 shows a schematic diagram illustrating an example of stripe-wise symbol detection in a second embodiment, and

FIG. 11 schematically illustrates the principle of cross-talk cancellation.

FIG. 1 shows an example of a recording and reproduction system. It comprises a source 1 for transmitting input symbols DI through a channel data stream 2, and a receiver 3 (also called reproduction apparatus) for receiving the symbols from the channel data stream and for delivering output symbols DO. In a typical data recording system the source 1 comprises transmission means 10, 20, 30, 40, for transmitting input symbols DI from a user data stream, the channel data stream 2 is a record carrier 50 for recording the transmitted symbols of the user data stream, and the receiver 3 comprises reception means 60, 70, 80, 90, for retrieving output symbols DO from said record carrier. In particular, the receiver 3 comprises a symbol detector 70 for detecting the symbol values retrieved from said record carrier.

Typical coding and signal processing elements of such recording and reproduction system will now be described with respect to FIG. 1. The cycle of user data from input DI to output DO can include interleaving 10, error-correction-code (ECC) and. modulation encoding 20, 30, signal preprocessing 40, data recording on the recording medium 50, signal post-processing 60, binary detection 70, and decoding 80, 90 of the modulation code and of the interleaved ECC. The ECC encoder 20 adds redundancy to the data in order to provide protection against errors from various noise sources. The ECC-encoded data are then passed on to a modulation encoder 30, which adapts the data to the channel, i.e. it manipulates the data into a form less likely to be corrupted by channel errors and more easily detected at the channel output. The modulated data are then input to a recording device, e.g. a spatial light modulator or the like, and recorded in the recording medium 50. On the retrieving side, the reading device (e.g. photo-detector device or charge-coupled device (CCD)) returns pseudo-analog data values, which must be transformed, back into digital data (one symbol per pixel for binary modulation schemes). The first step in this process is a post-processing step 60, called equalization, which attempts to undo distortions created in the recording process, possibly in the pseudo-analog domain. Then the array of (pseudo-analog) values is converted to an array of binary digital data via a bit detector 70. The array of digital data is then passed first to the modulation decoder 80, which performs the inverse operation to modulation encoding, and then to an ECC decoder 90.

In CD (Compact Disc), DVD and BD, the physical coding format is based on a one-dimensional single spiral. In 2D optical recording, the concept of a broad spiral is introduced, which consists in a two-dimensional area built up from a number of adjacent rows of bits, or tracks, stacked one upon the other in a coherent fashion on a common underlying lattice of bits.

In the European patent application EP 01203878.2 the 2D constrained coding on hexagonal lattices in terms of nearest-neighbor clusters of channel bits is described. Therein, it has been focused mainly on the constraints with their advantages in terms of more robust transmission over the channel, but not on the actual construction of such 2D codes. The latter topic is addressed in the European patent application 02076665.5, i.e. the implementation and construction of such a 2D code is described therein. By way of example, a certain 2D hexagonal code shall be illustrated in the following. However, it should be noted that the general idea of the invention and all measures can be applied generally to any 2D code, in particular any 2D hexagonal or square lattice code.

FIG. 2 illustrates the principle of meta-band-based 2D coding used in 2D optical recording that can be implemented for coding data on a recording medium such as e.g. an optical disc. A meta-band comprises a number of bit-rows. The code evolves along a one-dimensional first direction (tangential i.e. parallel to the tracks of the disc). A 2D meta-band consists of a number of 1D rows or tracks, stacked upon each other in a second direction (e.g. radial) substantially orthogonal to the first (tangential) direction. The broad spiral consists of a coherent stacking of meta-bands one upon the other. Between successive revolutions of the broad spiral a guard band of, for instance, one row high may be located.

FIG. 3A and 3B are diagrammatic top-views of 1D and 2D spirals, respectively, for illustrating both 1D and 2D coding concepts, the latter being based on a hexagonal lattice of bits. Channel bits in the broad spiral are indicated as cells of a honeycomb structure.

As shown in FIG. 3B in the 2D storage format bits are stored on a 2-dimensional hexagonal lattice. A format with a so called ‘broad spiral’ is possible. The broad spiral contains N=11 so called ‘symbol rows’ of symbols, for instance bits. Each symbol row has the proper phase relation to build up the hexagonal lattice (i.e. each symbol row is shifted 180° with respect to the adjacent symbol rows). On a circular disc it is not possible to adhere to this phase relation across the complete disc because then the areal bit density would be a function of the radius of the disc. Therefore, the number of symbol rows in the broad spiral is limited and a so called ‘guard band’ is present between the spirals.

A schematic diagram of this format is shown in FIG. 4. In this example each spiral (also called symbol strip in the description above) B comprises 7 symbol rows r. The guard band g is empty (i.e. it contains no pits) and it separates contiguous spirals B0, B1, B2 to offer the possibility to break the phase relation that is needed to maintain the hexagonal lattice at fixed density across the complete disc (i.e. the spirals B are asynchronous with respect to each other). Additionally, the guard band g is a good point to start symbol-detection because its content is known. However, in order to use the information from the outer symbol-rows of the 2D spiral B that has leaked away into the guard band g, the sampled replay signal of the guard band g is used. Unfortunately, this replay signal is disturbed by inter-symbol interference (ISI) from the other, adjacent broad spiral B that has no phase relation with respect to the sampling phase of the current symbol-detection.

For a rotating disc system as described above, guard bands g are needed to separate successive circumferences of a broad spiral B so that the same density of the hexagonal lattice can be maintained at different radii of the disc. For other storage media, such as a card system (with an appropriate translation system), the latter problem does not occur, so that no guard bands are necessarily required, and a large-area continuous 2D format, preferably with a proper 2D synchronization structure, can be realized. However, a practical 2D drive will require a 2D read-out system with only a limited number of spots in the spot-array, so that a subset of symbol rows, the previously called 2D strip B, can be read at once. Supposing than N symbol rows shall be read at once, then information of the top and bottom symbol rows has leaked away in the symbol rows just neighboring the 2D strip. Opposite to the above mentioned embodiment of using a disc storage (thus using guard bands), these symbol rows contain “random” user data, while similar to the above mentioned embodiment these symbol rows contain ISI contributions from their neighboring symbol rows, further away from the 2D strip under consideration.

The problem underlying the present invention will now be discussed it in more detail. As argued before, the increase in density in 2D optical storage (at the same read-out physics of λ and NA) is based on the fact that all energy per symbol (bit) is used that is transmitted by the channel (in two dimensions). This means that to detect a certain symbol (bit) information from adjacent samples has to be used. One possible way to do this is to use e.g. a Viterbi symbol detector or a 2D PRML (partial-response maximum-likelihood) symbol detector. The present invention generally applies to any 2D Viterbi symbol detector. Unfortunately a full-fledged Viterbi symbol detector that incorporates most of the energy that is present in the impulse response must consider all possible symbol patterns in a considerable 2D array of symbols leading to a large number of states and a huge complexity: this is by far too complex and thus completely impractical. For this reason, more practical sub-optimal solutions for Viterbi symbol detection were found, among which a ‘stripe-wise Viterbi symbol detector will be explained in some more detail with respect to the present invention. Here only a few symbol rows, for instance three symbol rows are input to the detector. A possible state transition is schematically shown in FIG. 5 by the arrow. Another wide arrow indicates that only the detected output of the top row is used as “input” (in fact as side-information in the row adjacent to and above V₁) in the next Viterbi detection unit V₁ with a delay larger than or equal to the backtracking depth of the Viterbi detection unit V₀.

When going from one state to the other a branch metric is calculated as the sum of the three terms based on the three overlapping positions in the two states:

$$β = {\sum }_{i = 1}^{3} {( H {F}_{i} - {REF}_{i} )}^{2} .$$

Ref<i> denotes the reference value for the bit-cluster that results at bit-position i for the considered branch and the bits realized by the two states belonging to that branch. When most of the energy that is spread in 2D by the channel shall be incorporated, the samples on the guard band shall also be used because they contain the leaked-away information about the boundary row of the broad spiral due to inter-row cross-talk, i.e. the first Viterbi stripe is positioned as indicated in FIG. 5. In this case N+2 read-out spots, i.e. the N spots for parallel read-out of the N symbol rows of the strip B1 plus 2 spots Sg₀₁, and Sg₁₂ for the two guard bands separating the strips B0 from B1 and B1 from B2 , respectively) are required as shown in FIG. 6. Unfortunately, this sample also contains a signal fraction due to symbols in the next broad spiral as a result of cross-talk (XT) (also called “radial” inter-symbol interference (ISI) between the rows). For the positions outside the guard band but that are within the considered strip being processed, this ISI is incorporated in the reference level calculation by making use of the bits that are available in the state diagram of the Viterbi detector and in preliminary bit decisions for symbols outside the Viterbi-state diagram by propagation of side-information from one Viterbi processor to the next Viterbi processor. For the guard band position, however, these symbol decisions are not available because they are in the adjacent broad spiral. Moreover, these symbols in the neighbouring spiral may be asynchronous, that is, may show no fixed phase relation with respect to the symbols in the current spiral under consideration.

According to the present invention it is thus proposed to measure also the boundary row rb₀₁ of the adjacent strip B0 next to the guard band g₀₁ and the boundary row rb₂₁ of the adjacent strip B2 next to the guard band g₁₂ and to (separately) perform cross-talk cancellation (XTC) at the guard bands g₀₁ and g₁₂ using these rows r₀₁ and rb₂₁ as input. In that case the influence is not incorporated in the reference level, but the HF signal is compensated prior to the bit detection processing. Therefore, it is further proposed to read with another additional two spots Srb₀₁ and Srb₂₁ the signal from the first rows rb₀₁ and rb₂₁ of the adjacent broad spirals B0 and B2 and to implement two cross-talk cancellers for the guard bands g₀ and g₁ to separate the broad spirals B0, B1 and B2. The total number of read-out spots will thus be N+4 while the output number of symbol rows r of the spiral B1 equals N. A schematic diagram of the proposed symbol detection apparatus is shown in FIG. 7.

Also when a 2D equalizer is used to equalize towards the target response of the Viterbi detector it is beneficial to have a guard band signal that is free from cross-talk from adjacent broad spirals because these samples are used for example in the equalizer for the first and second row in case a two-shell 2D equalizer is used. For the cross-talk cancellation, which is schematically indicated in FIG. 7 by XTC units XTC1 and XTC2 conventional techniques like LMS, indicated by LMS units LMS1, LSM2, to adapt the-FIR filter taps of FIR filters FIR1, FIR2 in the XTC units can be used.

The XTC-unit always comprises a FIR filter; the adaptation of the filter-tap coefficients of the FIR-filter can be done with the LMS (Least-Mean-Squares) approach, for instance based on de-correlation; however, also other adaptation schemes may be devised, for instance, in the case the track-pitch (radial distance between bit-rows) becomes small enough yielding a high-level of coss-talk. In that case, the update of the coefficients may be done by use of the error-signal from the Viterbi bit detector, in the same sense as is done with an adaptive equalizer. It shall be noted that in FIGS. 7 and 8, the LMS unit must be considered as a generalized block for adaptation of the FIR coefficients (without specification of the precise updating mechanism).

An embodiment of a symbol detection apparatus for the case of using a continuous 2D format for storage of the channel data stream is shown schematically in FIG. 8. The similarity with the embodiment shown in FIG. 7 is obvious when revealing the differences as the following two aspects:
(i) The channel data stream is continuously stored in a large 2D area without the separation in to symbol strips by use of guard bands. The guard bands of the embodiment of FIG. 7 can thus be filled with random data
(ii) There is no spiral in this case, which can be mimiced in the previous case by assuming a phase-relation between adjacent spirals that is equal to the phase-relation of successive symbol rows of the 2D (hexagonal) symbol lattice.

When N symbol rows shall be detected, we use N+4 read-out spots in the spot-array, and a 2D Viterbi symbol detector (or a sub-optimal variant of it) for joint symbol-detection on N+2 symbol rows. The signal waveforms from the outer two spots of the spot-array numbered 0 and N+3 (and thus coincident with the outer two symbol rows r₀ corresponding to rb₀₁ in FIG. 7 and r_{N+3} corresponding to rb₂₁ in FIG. 7) are used for cross-talk cancellation on the signals of their neighbouring spots, numbered 1 and N+2. After this operation, the only difference that is left with respect to the situation illustrated in FIG. 7 is that the symbol rows at the location of the guard band (numbered 1 and N+2) contain unknown symbols, which have to be detected together with the wanted symbol rows r₂ up to r_{N+1}).

As mentioned above different kinds of symbol detectors can be employed according to the invention. It is preferred to do a kind of per “small number of” tracks symbol detection, so-called stripe-by-stripe or stripe-wise symbol detection to decode the 2D information encoded on the broad spiral. The simplest embodiment of the invention uses a 2-track Viterbi bit detector, that is, a stripe consists then of two bit rows. Examples described hereafter with respect to the following figures relate to this simple embodiment, which is not restrictive. Using any n-track (n>0) trellis-based symbol detector (that is, a stripe consists of n bit rows) will fall within the scope of the invention. Nevertheless, using stripes of 1 track high gives worse BER (Bit Error Rate) versus SNR (Signal to Noise Ratio) performance.

FIG. 9 illustrates the detecting method in accordance with this simple embodiment, which uses a 2-track Viterbi bit detector T. The principle of the one-dimensional Viterbi bit detection, which comprises only a single row of bits, is well known in the state of the art for one-dimensional modulation and coding. It is for instance described in Chapter 7, particularly in paragraphs 7.1, 7.2, 7.3 and 7.5 “Viterbi Detection” by Jan Bergmans, “Digital Baseband Transmission and Recording”, Kluwer Academic Publishers, 1996.

In accordance with the invention, the 2-track Viterbi bit detection comprises the following steps. In a first step, bit detection is performed for the bits in the top two tracks. Since the first track is adjacent to the guard space between the successive revolutions of the broad spiral, error-free side information (e.g. zeroes) is used in the computation of the hypothetical channel outputs (or, detected channel bits) that label the branches of the Viterbi trellis. This significantly increases the reliability with which the tracks adjacent to the guard space can be estimated. Bit-detection errors might occur in the first two tracks due to the fact that the bits in the 3rd, 4th, etc . . . track are unknown and are not modeled correctly in this first decoding attempt. E.g. they all can be set to only zeroes, ones, random, alternating 0-1, or a “special” value which lies in between 0 and 1 and 15 which indicates a channel output value in between a corresponding channel input value of 0 or 1. Another alternative for these bits outside of the current two-track stripe is to use preliminary bit-decisions coming from a very simple threshold detector. Since the 2nd track was closest to these unknown tracks it is deemed the most unreliable.

Next, the 2-track Viterbi bit detector is shifted one track down, and is operated again over the 2nd and 3rd track. Now, the hard-decision bits of the 1 st track and 4-th track serve as side information in the computation of the hypothetical channel outputs (or, channel bits) that label the branches of the trellis etc. until all tracks have been detected. During the detection of the 2nd and 3rd track, the estimated bits for the 2nd and 3rd track are overwritten. Like this, each time, the track closest to the guard space remains while the other is overwritten. In general, the reliability of the estimated bits closest to the guard space will be the highest

When the procedure is restarted again at the first track for a second iteration of the same procedure, a first estimate for the bits of the 3rd (and 4th) track, that are adjacent to. the top two tracks, is already available for the computation of the hypothetical channel outputs that label the Viterbi trellis to be used as side information at tracks above and tracks below the current stripe of tracks to be detected. Thus, during this second pass, the number of bits in error will generally decrease significantly due to better side information obtained from the previous iteration of the stripe-wise detection over the complete broad spiral, or a part thereof.

FIG. 10 illustrates an embodiment of one iteration with 2-track Viterbi bit detector machines. Once the first 2-track Viterbi bit detector has output its first estimates of the first (and second) track, with a certain fixed, quite small delay (known as back-tracking delay), a second 2-track Viterbi bit detector can start working on the 2nd (and 3rd) track, while using the output of the first Viterbi machine for the first track as side information etc. This way, 10 machines are needed per iteration, for three iterations it amounts to 30 Viterbi machines. In case a train of 10 2-track Viterbi bit detectors is used, for three repeats of the iterative procedure (“iterations of iterations”), the hard bits obtained during the stripe-wise processing one repeat earlier on row i+1 is used for row i−1, i during the second repeat. The hard bits of adjacent tracks to the stripe are needed to compute the channel outputs above the stripe for all the branches in the trellis based processing. More details and embodiments of a stripe-wise symbol detector are described in the above mentioned European patent application 02292937.6 (PHNL 021237).

Also for cross-talk cancellation different embodiments can be used according to the invention. One embodiment of an XTC block shown above uses an LMS unit and an FIR filter. The principle used therein shall be explained with reference to FIG. 11. Shown are two symbol rows, for instance the lower boundary row rb₀₁ of strip B0 and the guard band g₀₁, separating strips B0 and B1 (see FIG. 7). Then, cross-talk (that is, radial inter-symbol interference) shall be cancelled so that there is no radial ISI present in the guard band g₀₁. By use of two read-out spots the raw HF signals Sₘ⁺(for the boundary row rb₀₁) and Cₘ (for the guard band g₀₁) are measured. From these signals a filtered central-spot signal Cₘ* is calculated as

$${C}_{m}^{*} = {C}_{m} - {\sum }_{k} {f}_{k}^{+} {S}_{m - k}^{+} .$$

The result of this XTC block is that the resulting signal waveform Cₘ* is (almost) “free” of any cross-talk from the adjacent symbol row in the neighbouring strip. It makes the strip under consideration (with its guard bands) independent from the neighbouring strips. The XTC block in fact “cuts” the strip under consideration out of its environment (eliminating as much as possible the ISI from the neighbouring strips on the guard bands of the current strip). Once this is done, the stripe-wise Viterbi symbol detector can proceed to process the signals of all the symbol rows of the current strip (or meta-spiral), together with its guard bands at both sides of the strip (for the case of the spiral-based format).

Different ways of cross-talk cancellation can be used according to the present invention. In general, there are three ways for determining the coefficients of the XTC FIR filters (independently for the upper spot and the lower spot):
(1) decorrelation of the corrected signal for the central spot and the raw signal of the signal for the side-spot; or
(2) minimizing the signal energy at transitions; or
(3) minimizing the energy in the error of a Viterbi bit detector.
   These three ways can be used according to the invention.

The present invention is not only applicable for the hexagonal lattice or for a disc-based format. In fact, it can be used on any 2D lattice where detection is done on limited blocks of data where blocks of data are separated by some ‘white space’ (like the guard band one of the above described embodiment) or are just continuous across a larger 2D area Also the use of the LMS algorithm for updating the taps of the FIR filter is not obliged. Any other update algorithm can also be used.

The present invention provides a solution for cross-talk cancellation in 2D symbol detection. Its purpose may depend slightly on the practical implementation of the 2D format, for which different cases are considered. For a first case with a 2D format based on a broad spiral (for a 2D disc), the purpose is to benefit from the information leaked away from the top symbol rows and bottom symbol rows of the spiral into the guard band that is present between two successive broad spirals. For a second case with a 2D format consisting of large areas of coherent and continuous 2D lattice, the purpose is to read-out sub-areas of the 2D area without the need to use a guard band, and still to be able to benefit from the leaked-away information across the boundaries of the considered 2D sub-area

1. Symbol detection apparatus for detecting the symbol values of a two-dimensional channel data stream recorded on a record carrier, said channel data stream comprising a set of contiguous symbol strips (B) of symbol rows (r) one-dimesionally evolving along a first direction and being aligned with each other along a second direction, said two directions constituting a two-dimensional lattice of symbol positions, comprising:
a cross-talk cancellation unit (XTC) for cancellation of radial inter-symbol interference present in the first adjacent symbol rows (g₀₁, g₀₂; r₁, r_{N+2}) of a symbol strip (B1) from the next but one adjacent symbol row (rb₀₁, rb₀₂; r₀, r_{N+3}) of said symbol strip (B1) by applying for each first adjacent symbol row (g₀₁, g₀₂; r₁, r_{N+2}) a cross-talk cancellation between a first adjacent symbol row (g₀₁, g₀₂; r₁, r_{N+2}) and its neighboring symbol row (rb₀₁, rb₀₂; r₀, r_{N+3}) not belonging to said symbol strip (B1), and
a 2D symbol detector (V) for symbol detection of the symbols of said symbol strip (B1) together with said first adjacent symbol rows (g₀₁, g₀₂; r₁, r_{N+2}).

2. Symbol detection apparatus as claimed in claim 1, wherein said first adjacent symbol rows are guard-band symbol rows (g₀₁, g₀₂) separating contiguous symbol strips (B0, B1, B2).

3. Symbol detection apparatus as claimed in claim 1, wherein said first adjacent symbol rows are the outer symbol rows (r₁, r_{N+2}) of the two neighboring symbol strips (B0, B2) of said symbol strip (B1).

4. Symbol detection apparatus as claimed in claim 1, wherein said 2D symbol detector (V) is a 2D PRML symbol detector, in particular a Viterbi detector, for iterative stripe-wise symbol detection of the symbols of a stripe (T), a stripe (T) comprising at least two neighboring symbol rows.

5. Symbol detection apparatus as claimed in claim 1, wherein said cross-talk cancellation unit (XTC) comprises an FIR filter unit (FIR) and an updating unit (LMS) for updating of the coefficients of said FIR filter.

6. Symbol detection method for detection the symbol values of a two-dimensional channel data stream recorded on a record carrier, said channel data channel data stream comprising a set of contiguous symbol strips (B) of symbol rows (r) one-dimensionally evolving along a first direction and being aligned with each other along a second direction, said two directions constituting a two-dimensional lattice of symbol positions, comprising the steps of:
cancellation of radial inter-symbol interference present in the first adjacent symbol rows (g₀₁, g₀₂; r₁, r_{N+2}) of a symbol strip (B1) from the next but one adjacent symbol row (rb₀₁, rb₀₂; r₀, r_{N+3}) of said symbol strip (B1) by applying for each first adjacent symbol row (g₀₁, g₀₂; r₁, r_{N+2}) a cross-talk cancellation between a first adjacent symbol row (g₀₁, g₀₂; r₁, r_{N+2}) and its neighboring symbol row (rb₀₁, rb₀₂; r₀, r_{N+3}) not belonging to said symbol strip (B1), and
symbol detection of the symbols of said symbol strip (B1) together with said first adjacent symbol rows (g₀₁, g₀₂; r₁, r_{N+2}). by use of a 2D symbol detector (V).

7. Reproduction apparatus for reproduction of a user data stream from a two dimensional channel data stream recorded on a record carrier, comprising a symbol detection apparatus as claimed in claim 1 for detecting the symbol values of said two-dimensional channel data stream.

8. Reproduction apparatus for reproduction of a user data stream from a two dimensional channel data stream recorded on a record carrier, comprising a symbol detection method as claimed in claim 6 for detecting the symbol values of said two-dimensional channel data system.

9. Computer program comprising program code means for causing a computer to carry out the steps of the method as claimed in claim 1 when said computer program is run on a computer.
